(19) United States
(12) Patent Application Publication
(10) Pub. No.: US 2007/0273010 A1
(43) Pub. Date: Nov. 29, 2007

(54) Design and Method for Attaching a Die to a Leadframe in a Semiconductor Device

(75) Inventors: Jeffrey G. Holloway, Plano, TX (US); Steven A. Kummerl, Carrollton, TX (US); Bernhard P. Lange, Freising (DE)

Correspondence Address: TEXAS INSTRUMENTS INCORPORATED, P O BOX 655474, M/S 3999, DALLAS, TX, 75265, US

(73) Assignees: TEXAS INSTRUMENTS INCORPORATED, Dallas, TX (US); TEXAS INSTRUMENTS DEUTSCHLAND GMBH, Freising (DE)

(21) Appl. No.: 11/754,456

(22) Filed: May 29, 2007

Related U.S. Application Data
(60) Provisional application No. 60/882,426, filed on Dec. 28, 2006.

(30) Foreign Application Priority Data
May 29, 2006 (DE) 102006024943.7

(51) Int. Cl. H01L 23/495; H01L 21/00

(52) U.S. Cl. 257/666; 438/106

(57) ABSTRACT

The semiconductor device whose structure is formed from a die attached to a leadframe comprises a die having an attachment member, and a leadframe having a recess configured to receive a corresponding attachment member so as to establish a connection between the die and the leadframe.

The present invention generally relates to a design and method for attaching a die to a leadframe in a semiconductor device. More particularly, but not exclusively, the present invention relates to a design and manufacturing method for flip chip attach in molded plastic leadless flat packages.

### BACKGROUND

Semiconductor devices comprising chips (dies) are typically made with bumps of metal on their active surface, which are used to connect the die to a metal leadframe electrically and physically. The process of connection may be formed using any of three methods.

The first method uses temperature to melt the bumps—in this case made of solder—so that they wet to the surface of the leadframe. Upon cooling the bumps then solidify to form a connection between the die and the leadframe. The second method uses force and temperature to cause interdiffusion between the metals at the surface of the bump and the surface of the leadframe, without the bump ever actually melting (thermal compression or thermo sonic bonding). The third is to make the bumps of metal that will not melt due to temperature excursions from processing, for example copper, and to deposit a small amount of solder paste on the surfaces of the leadframe where they will be contacted by the bumps during die attach. Temperature is then used to melt the solderpaste which forms a solder joint to the bump. In each case the result is a die attached to a leadframe by metal bridges or bumps with the die separated from the leadframe by the thickness of those bumps. The die and frame assembly are then overmolded with a molding compound or encapsulant that adds mechanical support while leaving portions of the leadframe exposed for electrical connection to a printed circuit board or other substrate.

Electrical connectivity takes place through the bumps. Also the bumps serve as a primary path for removal of heat from the device during operation. More heat may be removed by adding further bumps and bonding them to leadframe features.

A disadvantage of both of the above-described methods is that the bump bonding process must be carefully controlled to maintain consistent bump height; i.e., the distance from die to leadframe. Also, the semiconductor device package, consisting of the die and leadframe, becomes very thick when connected by solder bumps. Furthermore, extra bumps required for heat removal from the die take up space required for active circuitry and require enlargement of the die surface area.

The present invention has been devised with the foregoing in mind.

### SUMMARY

The present invention provides a semiconductor device, comprising a die having an attachment member, and a leadframe, the leadframe having a recess configured to receive a corresponding attachment member so as to establish a connection between the die and the leadframe. The attachment member can be a bump (formed of solder or any other material suitable for electrical and thermal conduction) and the recess can be formed by reducing the thickness of the leadframe in selected areas from above, for example by patterned etching. The recess should preferably be formed to have a height corresponding to the expected height of the bump after bonding of the die to the leadframe has taken place, so that the recess can receive and accommodate the bump. This reduces the distance between the die and the leadframe and allows a thinner device package to be obtained, or a thicker leadframe to be used.

The leadframe can be designed with a full thickness heat sink formed from a central portion of the leadframe. In this case the heatsink is centred in the die but electrically separate from pins formed in a peripheral portion of the leadframe. When the die is attached to the leadframe, the pins are bonded to the die so as to be provided on the outer periphery of the die. Thus, when the die is bonded by the bumps to the leadframe, the central passivated section of the die is pressed against the central heat sink. In the case of bonding by soldering the bumps to the die, the die is then supported by the heat sink, thus preventing the solder bumps from collapsing too far or spreading too widely. Alternatively, the pins may form the heatsink and be electrically connected to the central portion of the leadframe, for example by forming the pins and the central portion integrally. In both cases the recesses can be provided in either the pins or the central portion of the leadframe, or both.

A thermal grease, liquid adhesive or film adhesive or protective coating may also be provided between the die and the leadframe to increase thermal conduction and help maintain mechanical integrity, or protect the surface of the die from mechanical damage during the assembly process. The device may then be encapsulated, for example by a plastic molding compound.

The present invention also provides a method of attaching a die to a leadframe in a semiconductor device, the method comprising providing an attachment member on the die, forming a recess in the leadframe and configuring the recess to receive a corresponding attachment member so as to connect the die to the leadframe.

### BRIEF DESCRIPTION OF THE DRAWINGS

Additional characteristics and advantages of the invention ensue from the description below of the preferred embodiments and from the accompanying drawings, in which:

FIGS. 1A to 1D are side views of a semiconductor device according to a first embodiment of the present invention;

FIG. 1E is a top view of a semiconductor device according to the first embodiment of the present invention;

FIG. 2A is a side view of a semiconductor device according to a second embodiment of the present invention;

FIG. 2B is a top view of a semiconductor device according to the second embodiment of the present invention;

FIGS. 3A to 3D are side views of a semiconductor device according to a third embodiment of the present invention;

FIGS. 4A to 4D are side views of a semiconductor device according to a fourth embodiment of the present invention; and

FIG. 4E is a top view of a semiconductor device according to the fourth embodiment of the present invention.

### DETAILED DESCRIPTION

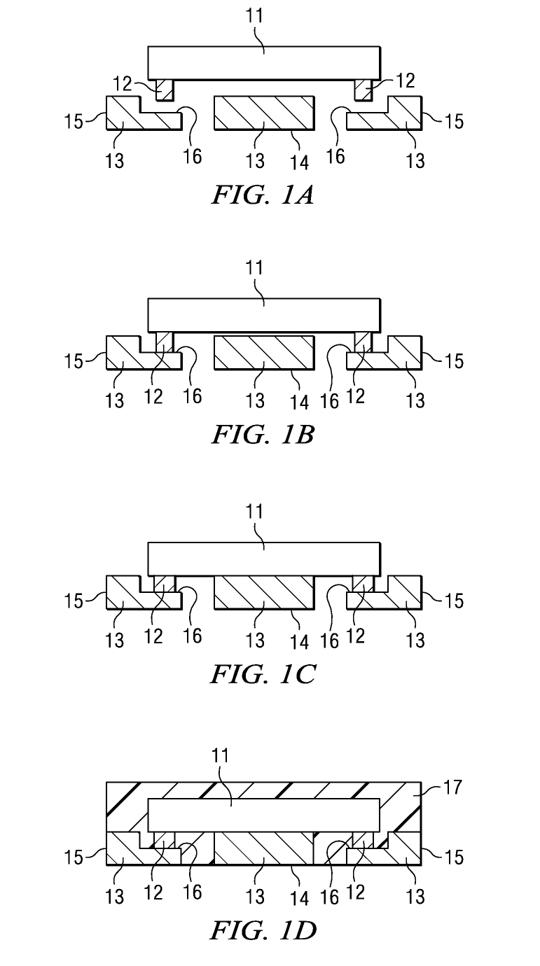

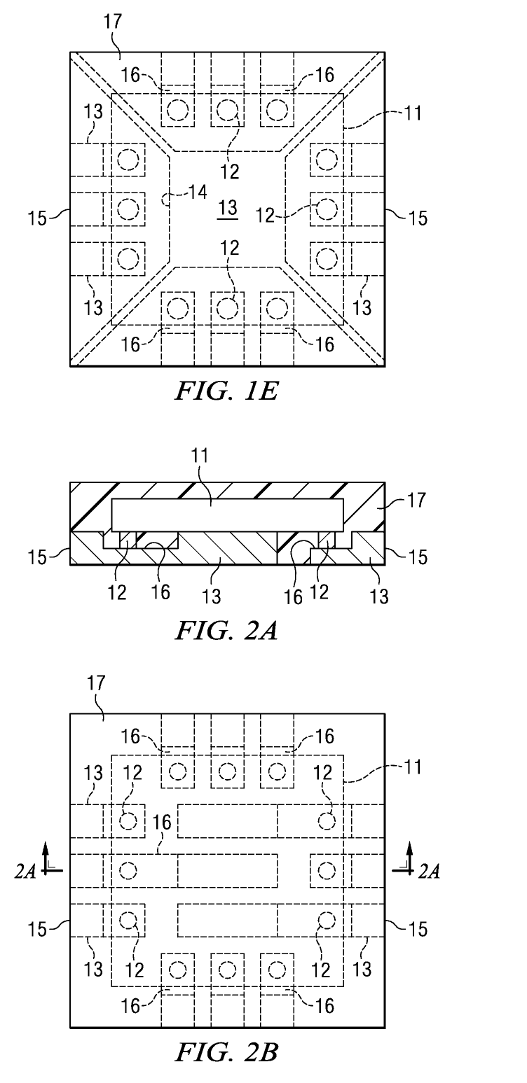

FIGS. 1A to 1E show a semiconductor device having a chip or die 11 provided with solder bumps 12 for attaching the die 11 to a leadframe 13. The leadframe 13 has a central heat sink portion 14, located so as to be centered in the die 11 when the die 11 is attached to the leadframe 13, and pins 15, located at peripheral portions of the leadframe 13. The pins 15 bond with the die 11 so as to electrically connect the die 11 to the leadframe 13. In this embodiment the central heat sink portion 14 is electrically separated from the pins 15. Recesses 16 are provided in the leadframe 13 in the pins 15 at positions where the solder bumps 12 on the die 11 will be bonded to the leadframe 13. The recesses 16 are formed by selectively thinning down the leadframe 13 from the bonding side, typically by patterned etching. The leadframe 13 is thinned by an amount equal to the expected height of the bumps 12 after soldering of the bumps 12 has taken place and the die 11 has been bonded to the leadframe 13.

FIG. 1A shows the device before the die 11 is bonded to the leadframe 13. In FIG. 1 B, the die 11 is brought into contact with the leadframe 13 so as to begin the process of attaching the die 11 to the leadframe 13.

In FIG. 1C the solder bumps 12 are melted. As the bumps 12 melt and collapse downwards, a central section of the die 11 is pressed against the central heat sink portion 14 of the leadframe 13. The heat sink 14 supports the die 11, thus preventing the solder bumps 12 from collapsing too far. It can be seen that the recesses 16 are configured to be the same height as the solder bumps 12 after bump reflow (melting of the solder or solder paste) has taken place. Thus, when the die 11 is attached to the leadframe 13, the bonding surface of the die 11 is flush with the uppermost surface of the leadframe 13 and there is at least partial contact between the bonding surfaces of the die 11 and the leadframe 13. This allows heat to be conducted away from the die 11 through the leadframe 13.

The device may be given added mechanical strength by encapsulating the die 11 and leadframe 13, as shown in FIG. 1 D. The device may be encapsulated in whole or in part by a mold compound 17, for example epoxy resin based or other appropriate plastic material. However, the contact areas of the device at pins 15 are not encapsulated so that they are free to allow electrical connection to the device.

FIGS. 2A and 2B show a semiconductor device having a die 11 attached to a leadframe 13. The leadframe 13 comprises pins 15 provided with recesses 16. The die 11 is provided with solder bumps 12 configured to fit into corresponding recesses 16 when the die 11 is bonded to the leadframe.

In this embodiment, some of the pins 15 extend from a peripheral portion of the leadframe 13 into a central portion so that the pins themselves are used as the heat sink. The recesses 16 are formed in the leadframe 13 by top etching of the leadframe 13. As with the first embodiment, the recesses 16 are configured to be the same height as the solder bumps 12 after melting of the bumps 12 or solder paste has taken place and the die 11 is bonded to the leadframe 13, so that the recesses 16 can receive and accommodate the bumps 12.

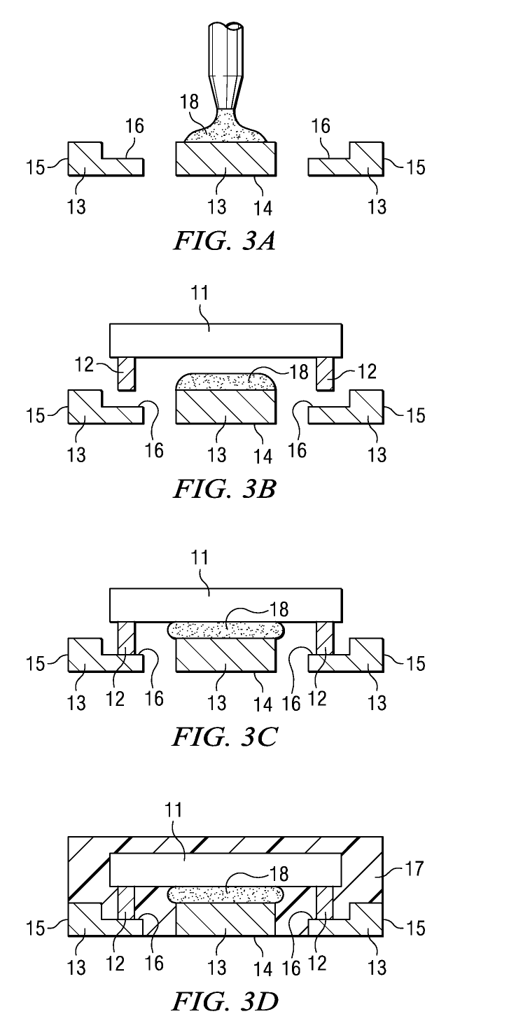

FIGS. 3A-3D show an alternative embodiment where the bumps 12 are not soldered to the leadframe but are instead bonded to the leadframe thermo sonically or by thermal compression. In this case the recesses 16 may not completely accommodate the bumps 12, causing an air gap to be left between the die 11 and the leadframe 13. Therefore a thermal conductor 18 is placed between the die 11 and the leadframe 13 to promote thermal conduction between the die 11 and the leadframe 13. The thermal conductor 18 may be a thermal grease, a liquid adhesive or a film adhesive, for example.

In FIG. 3A the thermal conductor 18 is applied to the central heat sink portion 14 of the leadframe. The die 11, being provided with bumps 12, is then brought into position over the leadframe 13, as shown in FIG. 3B, such that the die 11 itself is centered over the central heat sink portion 14 of the leadframe 13 and the bumps 12 are positioned over the recesses 16 provided in the pins 15. In FIG. 3C the bumps 12 are attached to the pins 15 in the recesses 16 by thermal compression or thermo sonic bonding. During that process the die 11 is brought into contact with the conductor 18. A thermal connection between the die 11 and the leadframe 13 is thus established via the thermal conductor 18 that is sufficient to allow heat to be conducted away from the die 11.

The device of this embodiment may also be encapsulated by a mold compound 17 to provide additional mechanical strength. Alternatively, the mold compound 17 may be made from a thermally conducting material and be configured to fill the gap between the die 11 and the central heat sink portion 14 so as to establish a thermal connection between the die 11 and the leadframe 13. In this case the mold compound 17 would replace the thermal conductor 18 as a means of conducting heat away from the die 11 to the leadframe 13.

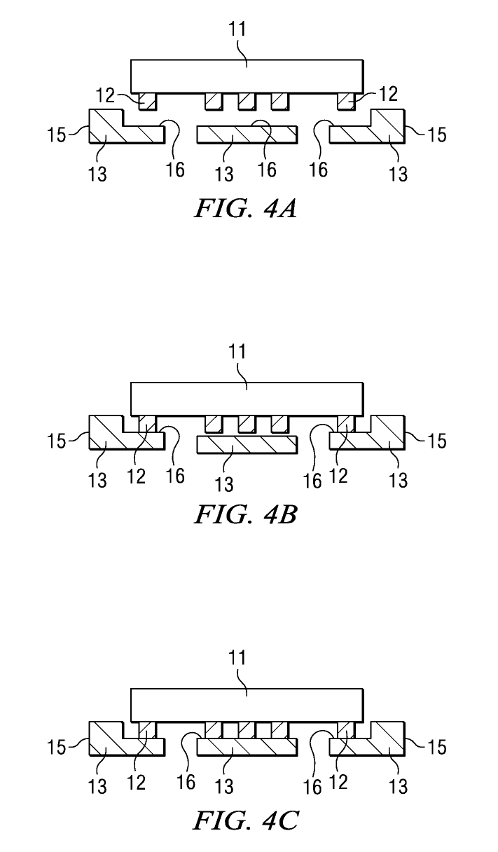

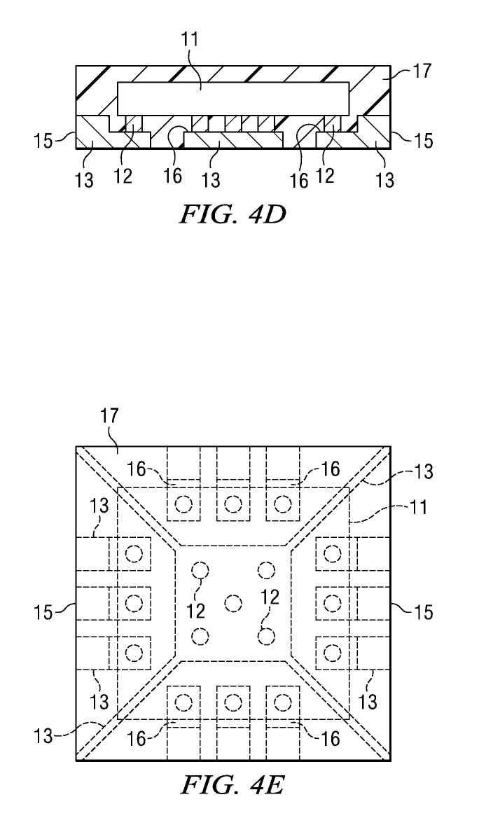

A further embodiment of the semiconductor device is shown in FIGS. 4A-4E. The die 11 is provided with bumps 12 for attachment to the leadframe 13. However, in this embodiment, the leadframe 13 itself does not act as a heat sink—all thermal conductivity takes place through the bumps 12.

FIG. 4A shows the die 11 positioned over the leadframe 13. Both the central section of the leadframe 13 and the pins 15 in the periphery of the leadframe 13 have been top etched to form recesses 16. The recesses 16 are configured to accommodate bumps 12. In FIG. 4B the die 11 is moved towards the leadframe 13 so that the bumps 12 are brought into contact with the leadframe 13 and in FIG. 4C the bumps 12 are bonded to the leadframe 13 so that they are accommodated in the recesses 16. A thermal and electrical connection is thus established between the die 11 and the leadframe 13. As with the previous embodiments, the recesses 16 are etched so as to have the same height as the bumps 12 after the die 11 is attached to the leadframe 13. In this way, the bonding surface of the die 11 is flush with the uppermost surface of the leadframe 13. However, the central portion of the leadframe 13 does not have to be completely etched. It could also be selectively etched so as to provide for dies having different bump heights in combination with heat sink sections.

The device is then encapsulated by a mold compound 17, except at the contact points, as shown in FIG. 4D.

The invention has been described hereinabove with reference to specific embodiments. However the invention is not limited to these embodiments and no doubt alternatives will occur to the skilled person which fall within the scope of the claims.

For example, the embodiments described where the bumps 12 are soldered to the leadframe 13 could also be realized for the case where the bumps 12 are bonded to the leadframe 13 by an alternative means (for example by thermal compression), and vice versa.

What is claimed is:

1. A semiconductor device, comprising:
a die having a first thickness and an attachment member having a height; and
a leadframe having a second thickness, further having a peripheral portion and a central portion and further having a recess configured to receive a corresponding said attachment member;
a joint assembly including the die and the leadframe and the attachment member, wherein the thickness of the assembly is less than the sum of the first thickness and the second thickness and the height of the attachment member.

2. The semiconductor device according to claim 1, wherein the recess is provided in a peripheral portion of said leadframe.

3. The semiconductor device according to claim 1, wherein the recess is provided in a central portion of said leadframe.

4. The semiconductor device according to claim 1, wherein the central portion is electrically isolated from the peripheral portion.

5. The semiconductor device according to claim 1, wherein the central portion and the peripheral portion are electrically connected.

6. The semiconductor device according to claim 5, wherein the central portion and the peripheral portion are formed integrally.

7. The semiconductor device according to claim 1, wherein the recess equals to a height of said at least one attachment member when the die is connected to the leadframe.

8. The semiconductor device according to claim 1, further comprising an adhesive between the die and the leadframe.

9. The semiconductor device according to claim 1, wherein the recess is an etched recess.

10. The semiconductor device according to claim 1, further comprising a mold configured to encapsulate the die and a portion of the leadframe.

11. A method; comprising:
providing a die having a first thickness;
providing an attachment member of a height on the die and;
providing a leadframe having a second thickness, further having a peripheral portion and a central portion, and further having a recess configured to receive a corresponding said attachment member; and
placing the attachment member in a corresponding recess thereby forming a joint assembly including the die, the leadframe and the attachment member, and wherein the assembly is thinner than the sum of the first thickness and the second thickness and the height of the attachment member.

12. The method according to claim 11, further comprising etching a portion of the leadframe thereby forming the recess.

13. The method according to claim 12, wherein the recess is in a central portion of the leadframe.

14. The method according to claim 12, wherein the recess is in a peripheral portion of the leadframe.

15. The method according to claim 11, comprising electrically isolating said central portion from said peripheral portion.

16. The method according to claim 11, comprising electrically connecting said central portion and said peripheral portion.

17. The method according to claim 15, comprising forming said central portion and said peripheral portion integrally.

18. The method according to claim 11, wherein the recess is equal to the height of said at least one attachment member when the die is joined to the leadframe.

19. The method according to claim 11, further comprising providing an adhesive between the die and the leadframe.

20. The method according to any one of claim 11, further comprising encapsulating the die and the leadframe in a mold.
